(19) United States
(12) Patent Application Publication
(10) Pub. No.: US 2025/0386701 A1
(43) Pub. Date: Dec. 18, 2025

(54) DISPLAY DEVICE AND METHOD OF MANUFACTURING THE DISPLAY DEVICE

(71) Applicant: Samsung Display Co., LTD., Yongin-si (KR)

(72) Inventor: HYUNEOK SHIN, Yongin-si (KR)

(21) Appl. No.: 19/050,437

(22) Filed: Feb. 11, 2025

(30) Foreign Application Priority Data
Jun. 18, 2024 (KR) 10-2024-0078828

(51) Int. Cl. H10K 59/131; H10K 59/12; H10K 59/124

(52) U.S. Cl. CPC H10K 59/1315; H10K 59/1201; H10K 59/124

(57) ABSTRACT

A display device includes: a first electrode disposed on the substrate, a first light emitting layer disposed on the first electrode, a first metal pattern disposed on the first light emitting layer and overlapping an edge of the first light emitting layer in a plan view, a second metal pattern disposed on the first metal pattern and at least partially overlapping the first metal pattern in the plan view, a side insulating layer covering side surface of the first light emitting layer, a side surface of the first metal pattern, a side surface of the second metal pattern, and an upper surface of the second metal pattern, and a second electrode disposed on the first light emitting layer.

This application claims priority to Korean Patent Application No. 10-2024-0078828,filed on Jun. 18, 2024, and all the benefits accruing therefrom under 35 U.S.C. § 119, the content of which in its entirety is herein incorporated by reference.

### BACKGROUND

### 1. Field

Embodiments relate to a display device and a method of manufacturing the display device. More particularly, embodiments relate to a display device providing visual information and a method of manufacturing the display device.

### 2. Description of the Related Art

A display device is a device that may display an image for providing visual information to a user. Among display devices, an organic light emitting diode display device has recently attracted attention.

A display device may include a light emitting layer emitting light. The light emitting layer may be formed using a metal mask or a fine metal mask (“FMM”).

### SUMMARY

Embodiments provide a display device with improved quality.

Embodiments provide a method of manufacturing the display device.

A display device according to an embodiment includes a first electrode disposed on a substrate, a first light emitting layer disposed on the first electrode, a first metal pattern disposed on the first light emitting layer and overlapping an edge of the first light emitting layer in a plan view, a second metal pattern disposed on the first metal pattern and at least partially overlapping the first metal pattern in the plan view, a side insulating layer covering a side surface of the first light emitting layer, a side surface of the first metal pattern, a side surface of the second metal pattern, and an upper surface of the second metal pattern, and a second electrode disposed on the first light emitting layer.

In an embodiment, the second metal pattern may protrude further than the first metal pattern and form an undercut area.

In an embodiment, the first electrode may be disposed in a first pixel area, and the second metal pattern may protrude further toward a center of the first pixel area than the first metal pattern.

In an embodiment, the second metal pattern may include another side surface opposite to the side surface of the second metal pattern in a cross-sectional view, and an inner side surface of the side insulating layer and the other side surface of the second metal pattern may be disposed on a same plane.

In an embodiment, the second electrode may cover the other side surface of the second metal pattern and the inner side surface of the side insulating layer.

In an embodiment, the first metal pattern may include another side surface opposite to the side surface of the first metal pattern in a cross-sectional view, the second metal pattern may include another side surface opposite to the side surface of the second metal pattern in the cross-sectional view, and the second electrode may cover the other side surface of the first metal pattern and the other side surface of the second metal pattern.

In an embodiment, the second electrode may further cover an inner side surface of the side insulating layer.

In an embodiment, the display device may further include a third electrode disposed on the substrate and spaced apart from the first electrode in the plan view and a second light emitting layer disposed on the third electrode and spaced apart from the first light emitting layer in the plan view.

In an embodiment, the side insulating layer may extend from the first light emitting layer to the second light emitting layer.

A display device according to an embodiment includes a first electrode disposed on a substrate, a light emitting layer disposed on the first electrode, a metal pattern disposed on the light emitting layer, a side insulating layer covering a side surface of the light emitting layer, a side surface of the first portion of the metal pattern, a side surface of the second portion of the metal pattern, and an upper surface of the second portion of the metal pattern, and a second electrode disposed on the light emitting layer.

In an embodiment, the metal pattern may include a first portion overlapping an edge of the light emitting layer in a plan view and a second portion disposed on the first portion, at least partially overlapping the first portion in the plan view, and having a larger width than the first portion.

In an embodiment, the second portion of the metal pattern may include another side surface opposite to the side surface of the second portion of the metal pattern in cross-sectional view, and an inner side surface of the side insulating layer and the other side surface of the second portion of the metal pattern may be disposed on a same plane.

In an embodiment, the second electrode may cover the other side surface of the second portion of the metal pattern and the inner side surface of the side insulating layer.

In an embodiment, the first portion of the metal pattern may include a material different from a material included in the second portion of the metal pattern.

In an embodiment, the first portion of the metal pattern may include another side surface opposite to the side surface of the first portion of the metal pattern in a cross-sectional view, the second portion of the metal pattern may include another side surface opposite to the side surface of the second portion of the metal pattern in the cross-sectional view, and the second electrode may cover the other side surface of the first portion of the metal pattern and the other side surface of the second portion of the metal pattern.

In an embodiment, the second electrode may further cover an inner side surface of the side insulating layer.

A method of manufacturing a display device according to an embodiment includes forming a first electrode on a substrate, forming a preliminary light emitting layer covering the first electrode, forming a first metal layer covering the preliminary light emitting layer, forming a second metal layer covering the first metal layer, forming a light emitting layer by removing a portion of the preliminary light emitting layer, forming a first preliminary metal pattern by removing a portion of the first metal layer, forming a second preliminary metal pattern by removing a portion of the second metal layer, forming a preliminary side insulating layer covering the light emitting layer, the first preliminary metal pattern, and the second preliminary metal pattern, forming a side insulating layer by removing a portion of the preliminary side insulating layer, forming a first metal pattern by removing a portion of the first preliminary metal pattern, forming a second metal pattern by removing a portion of the second preliminary metal pattern, and forming a second electrode on the light emitting layer.

In an embodiment, the portion of the preliminary surface insulating layer and the portion of the second preliminary metal pattern may be simultaneously removed by a dry etching process.

In an embodiment, the portion of the first preliminary metal pattern may be removed through a wet etching process, and the first metal pattern may be formed such that a width of the first metal pattern is smaller than a width of the second metal pattern.

In an embodiment, the portion of the preliminary light emitting layer, the portion of the first metal layer, and the portion of the second metal layer may be simultaneously removed.

In an embodiment, the forming of the side insulating layer and the forming of the second metal pattern may include forming a photoresist layer in a non-light emitting area on the preliminary side insulating layer and removing a portion of the preliminary side insulating layer and a portion of the second preliminary metal pattern through a dry etching process.

A display device according to an embodiment includes a first electrode disposed on a substrate, a first light emitting layer disposed on the first electrode, a first metal pattern disposed on the first light emitting layer and overlapping an edge of the first light emitting layer in a plan view, a second metal pattern disposed on the first metal pattern and at least partially overlapping the first metal pattern in the plan view, a side insulating layer covering a side surface of the first light emitting layer, a side surface of the first metal pattern, a side surface of the second metal pattern, and an upper surface of the second metal pattern, and a second electrode disposed on the first light emitting layer.

Accordingly, the side insulating layer may protect the side surface of the first light emitting layer.

In some aspects, an inner side surface of the side insulating layer and another side surface opposite to the side surface of the second metal pattern may be disposed on a same plane. Accordingly, the second electrode may electrically contact the second metal pattern without being disconnected. Accordingly, resistance of the second electrode may be reduced. In some aspects, the side insulating layer and the second metal pattern may be simultaneously formed through a dry etching process. Accordingly, the side insulating layer and the second metal pattern may be easily formed at the same time.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to embodiments.

FIG. 2 is a cross-sectional view of the display device of FIG. 1 taken along line I-I′.

FIG. 3 is an enlarged cross-sectional view of area A of FIG. 2.

FIGS. 4, 5, 6, 7, 8, 9, 10, 11, 12, 13, 14, and 15 are cross-sectional views illustrating a method of manufacturing the display device of FIG. 2.

FIG. 16 is a block diagram illustrating an electronic device according to embodiments.

FIG. 17 is a diagram illustrating an example in which the electronic device of FIG. 16 is implemented as a smartphone.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

Aspects supported by the present disclosure may be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular. The term “substantially parallel” means approximately or actually parallel.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The term “adjacent” herein may refer to elements which are relatively close to each other (e.g., within a threshold distance) or elements which are in contact with each other. In some other cases, the term “adjacent” herein may refer to elements of the same type, in which another element of the same type is not disposed between the elements. For example, for a pixel area (e.g., first pixel area PX1) described as adjacent to another pixel area (e.g., second pixel area PX2), another pixel area is not present between the adjacent pixel areas.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

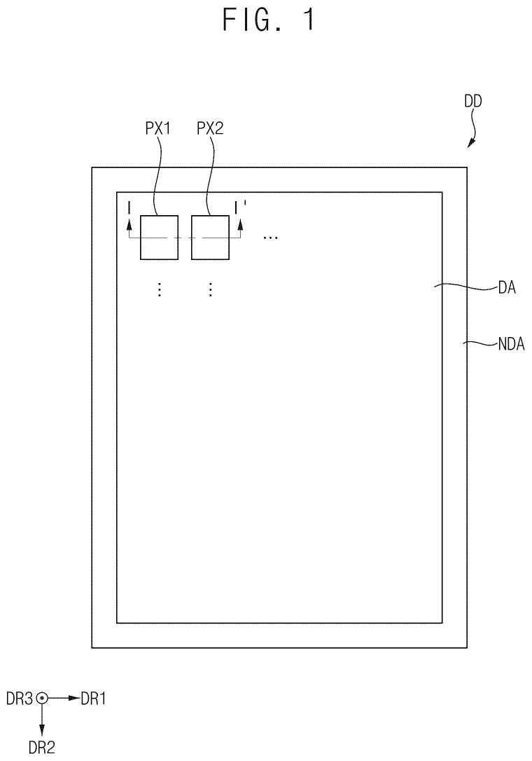

FIG. 1 is a plan view illustrating a display device according to embodiments.

Referring to FIG. 1, a display device DD according to an embodiment may include a display area DA and a non-display area NDA.

The display area DA may be an area that generates light or adjusts transmissivity of light provided from an external light source to display an image. A plurality of pixel areas may be disposed in the display area DA. For example, a first pixel area PX1 and a second pixel area PX2 may be disposed in the display area DA. Each of the plurality of pixel areas may emit light. For example, each of the first pixel area PX1 and the second pixel area PX2 may emit light.

The plurality of pixel areas may be disposed over the entire display area DA. Accordingly, the display area DA may display an image. In an embodiment, the plurality of pixel areas may be repeatedly arranged along a first direction DR1 and a second direction DR2 crossing the first direction DR1. For example, the second pixel area PX2 may be spaced apart from the first pixel area PX1 in the first direction DR1.

The non-display area NDA may surround at least a portion of the display area DA. A driver may be disposed in the non-display area NDA. The driver may provide a signal or a voltage to the plurality of pixel areas. For example, the driver may include a data driver, a gate driver, and/or the like. The non-display area NDA may not display an image.

In an embodiment, the first direction DR1 and the second direction DR2 crossing the first direction DR1 may be defined. For example, the second direction DR2 may be substantially perpendicular to the first direction DR1. However, this disclosure is not limited thereto, and the second direction DR2 may form an acute angle or an obtuse angle with the first direction DR1. In some aspects, a third direction DR3 crossing a plane formed by the first direction DR1 and the second direction DR2 may be defined. For example, the third direction DR3 may be substantially perpendicular to the plane formed by the first direction DR1 and the second directions DR2. However, this disclosure is not limited thereto, and the third direction DR3 may form an acute angle or an obtuse angle with the plane formed by the first direction DR1 and the second direction DR2.

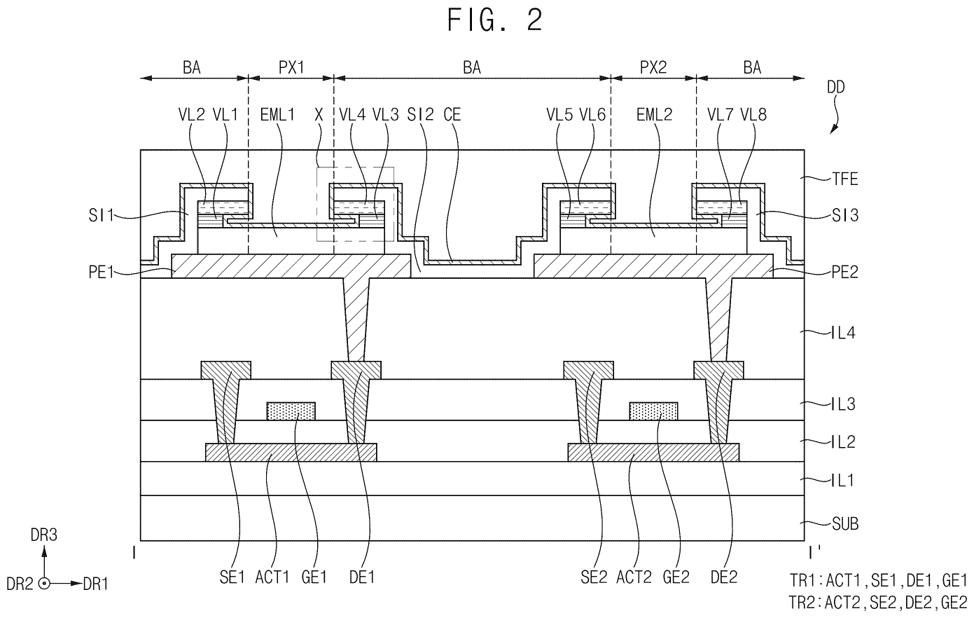

FIG. 2 is a cross-sectional view of the display device of FIG. 1 taken along line I-I′.

Referring to FIG. 2, the display device DD according to an embodiment may further include a non-light emitting area BA. The non-light emitting area BA may be disposed adjacent to the plurality of pixel areas. For example, the non-light emitting area BA may surround each of the plurality of pixel areas in a plan view. The non-light emitting area BA may be disposed between adjacent pixel areas among the plurality of pixel areas in a cross-sectional view. For example, as illustrated in FIG. 2, the non-light emitting area BA may be disposed between the first pixel area PX1 and the second pixel area PX2 in a cross-sectional view.

The display device DD according to an embodiment may include a substrate SUB, a first insulating layer IL1, a second insulating layer IL2, a third insulating layer IL3, a first transistor TR1, a second transistor TR2, a fourth insulating layer IL4, a first pixel electrode PE1, a second pixel electrode PE2, a first light emitting layer EML1, a second light emitting layer EML2, a first metal pattern VL1, a second metal pattern VL2, a third metal pattern VL3, a fourth metal pattern VL4, a fifth metal pattern VL5, a sixth metal pattern VL6, a seventh metal pattern VL7, an eighth metal pattern VL8, a first side insulating layer SI1, a second side insulating layer SI2, a third side insulating layer SI3, a common electrode CE, and an encapsulation layer TFE.

The first transistor TRI may include a first active pattern ACT1, a first contact electrode SE1, a second contact electrode DE1, and a first gate electrode GE1. The second transistor TR2 may include a second active pattern ACT2, a third contact electrode SE2, a fourth contact electrode DE2, and a second gate electrode GE2.

As the display device DD includes the first pixel area PX1, the second pixel area PX2, and the non-light emitting area BA, the substrate SUB may also include the first pixel area PX1, the second pixel area PX2, and the non-light emitting area BA. The substrate SUB may form a base of the display device DD.

The substrate SUB may include a transparent material or an opaque material. The substrate SUB may be formed of a transparent resin substrate. An example of the transparent resin substrate may include a polyimide substrate. In this case, for example, the polyimide substrate may include a first organic layer, a first barrier layer, a second organic layer, and the like. Alternatively, the substrate SUB may include a quartz substrate (e.g. a synthetic quartz substrate, a fluorine-doped quartz substrate), a calcium fluoride substrate, a sodalime glass substrate, a non-alkali glass substrate, or the like. These materials may be used alone or in combination with each other.

The first insulating layer IL1 may be disposed on the substrate SUB. The first insulating layer IL1 may prevent metal atoms or impurities from diffusing from the substrate SUB to the first transistor TRI and the second transistor TR2. In some aspects, the first insulating layer IL1 can improve flatness of a surface of the substrate SUB when the surface of the substrate SUB is not uniform.

For example, the first insulating layer IL1 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first active pattern ACT1 and the second active pattern ACT2 may be disposed on the first insulating layer IL1. For example, the first active pattern ACT1 may be disposed in at least a portion of the first pixel area PX1, and the second active pattern ACT2 may be disposed in at least a portion of the second pixel area PX2. That is, the first active pattern ACT1 and the second active pattern ACT2 may be spaced apart from each other in a plan view.

For example, each of the first active pattern ACT1 and the second active pattern ACT2 may include an inorganic semiconductor (e.g., amorphous silicon, poly silicon, metal oxide semiconductor), an organic semiconductor, and/or the like. These materials may be used alone or in combination with each other. Each of the first active pattern ACT1 and the second active pattern ACT2 may include a source area, a drain area, and a channel area disposed between the source area and the drain area.

The second insulating layer IL2 may be disposed on the first insulating layer IL1. The second insulating layer IL2 may sufficiently cover the first active pattern ACT1 and the second active pattern ACT2. For example, the second insulating layer IL2 may cover the first active pattern ACT1 and the second active pattern ACT2, and may be disposed along the profile of the first active pattern ACT1 and the second active pattern ACT2.

For example, the second insulating layer IL2 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1 and the second gate electrode GE2 may be disposed on the second insulating layer IL2. The first gate electrode GE1 may at least partially overlap the first active pattern ACT1 in a plan view. For example, the first gate electrode GE1 may overlap the channel area of the first active pattern ACT1 in a plan view. The second gate electrode GE2 may at least partially overlap the second active pattern ACT2 in a plan view. For example, the second gate electrode GE2 may overlap the channel area of the second active pattern ACT2 in a plan view. The first gate electrode GE1 and the second gate electrode GE2 may be spaced apart from each other in a plan view.

Each of the first gate electrode GE1 and the second gate electrode GE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

The third insulating layer IL3 may be disposed on the second insulating layer IL2. The third insulating layer IL3 may sufficiently cover the first gate electrode GE1 and the second gate electrode GE2. For example, the third insulating layer IL3 may cover the first gate electrode GE1 and the second gate electrode GE2 and may be disposed along the profile of the first gate electrode GE1 and the second gate electrode GE2.

For example, the third insulating layer IL3 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first contact electrode SE1, the second contact electrode DE1, the third contact electrode SE2 and the fourth contact electrode DE2 may be disposed on the third insulating layer IL3. The first contact electrode SE1 may be connected to the source area of the first active pattern ACT1 through a first contact hole defining through the second insulating layer IL2 and the third insulating layer IL3. The second contact electrode DE1 may be connected to the drain area of the first active pattern ACT1 through a second contact hole defining through the second insulating layer IL2 and the third insulating layer IL3. The third contact electrode SE2 may be connected to the source area of the second active pattern ACT2 through a third contact hole defining through the second insulating layer IL2 and the third insulating layer IL3. The fourth contact electrode DE2 may be connected to the drain area of the second active pattern ACT2 through a fourth contact hole defining through the second insulating layer IL2 and the third insulating layer IL3.

For example, each of the first contact electrode SE1, the second contact electrode DE1, the third contact electrode SE2 and the fourth contact electrode DE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

The fourth insulating layer IL4 may be disposed on the third insulating layer IL3. The fourth insulating layer IL4 may sufficiently cover the first contact electrode SE1, the second contact electrode DE1, the third contact electrode SE2 and the fourth contact electrode DE2.

In an embodiment, the fourth insulating layer IL4 may include an organic material. For example, the fourth insulating layer IL4 may include an organic material such as, for example, a phenolic resin, an acrylic resin, a polyimide resin, a polyamide resin, a siloxane resin, an epoxy resin, and/or the like. These materials may be used alone or in combination with each other.

The first pixel electrode PE1 and the second pixel electrode PE2 may be disposed on the fourth insulating layer IL4. The first pixel electrode PE1 may be disposed in the first pixel area PX1. In an embodiment, the first pixel electrode PE1 may be disposed in at least a portion of the non-light emitting area BA and in the first pixel area PX1. For example, the first pixel electrode PE1 may be disposed in the first pixel area PX1 and the non-light emitting area BA adjacent to the first pixel area PX1. The second pixel electrode PE2 may be disposed in the second pixel area PX2. In an embodiment, the second pixel electrode PE2 may be disposed in at least a portion of the non-light emitting area BA and in the second pixel area PX2. For example, the second pixel electrode PE2 may be disposed in the second pixel area PX2 and the non-light emitting area BA adjacent to the second pixel area PX2. The first pixel electrode PE1 and the second pixel electrode PE2 may be spaced apart from each other in a plan view. The first pixel electrode PE1 may be connected to the second contact electrode DE1 through a fifth contact hole defining through the fourth insulating layer IL4. In some aspects, the second pixel electrode PE2 may be connected to the fourth contact electrode DE2 through a sixth contact hole defining through the fourth insulating layer IL4.

Each of the first pixel electrode PE1 and the second pixel electrode PE2 may include a metal, an alloy, a metal nitride, a conductive metal oxide, a transparent conductive material, and/or the like. These materials may be used alone or in combination with each other. In an embodiment, each of the first pixel electrode PE1 and the second pixel electrode PE2 may have a stacked structure including ITO/Ag/ITO. For example, each of the first pixel electrode PE1 and the second pixel electrode PE2 may operate as an anode. In an embodiment, the first pixel electrode PE1 may be referred to as a first electrode, and the second pixel electrode PE2 may be referred to as a third electrode.

The first light emitting layer EML1 may be disposed on the first pixel electrode PE1. The first light emitting layer EML1 may at least partially overlap the first pixel electrode PE1 in a plan view. For example, the first light emitting layer EML1 may be disposed in the first pixel area PX1. In an embodiment, the first light emitting layer EML1 may be disposed in at least a portion of the non-light emitting area BA and in the first pixel area PX1. For example, the first light emitting layer EML1 may be disposed in the first pixel area PX1 and the non-light emitting area BA adjacent to the first pixel area PX1.

For example, the first light emitting layer EML1 may include a first functional layer including an organic material, an intermediate layer including a light emitting material and disposed on the first functional layer, and a second functional layer including an organic material and disposed on the intermediate layer. For example, the first functional layer may include a hole injection layer, a hole transport layer, and/or the like, and the second functional layer may include an electron transport layer, an electron injection layer, and/or the like.

The second light emitting layer EML2 may be disposed on the second pixel electrode PE2. The second light emitting layer EML2 may at least partially overlap the second pixel electrode PE2 in a plan view. For example, the second light emitting layer EML2 may be disposed in the second pixel area PX2. In an embodiment, the second light emitting layer EML2 may be disposed in at least a portion of the non-light emitting area BA and in the second pixel area PX2. For example, the second light emitting layer EML2 may be disposed in the second pixel area PX2 and the non-light emitting area BA adjacent to the second pixel area PX2.

For example, the second light emitting layer EML2 may include a first functional layer including an organic material, an intermediate layer including a light emitting material and disposed on the first functional layer, and a second functional layer including an organic material and disposed on the intermediate layer. For example, the first functional layer may include a hole injection layer, a hole transport layer, and/or the like, and the second functional layer may include an electron transport layer, an electron injection layer, and/or the like.

The first metal pattern VL1 and the third metal pattern VL3 may be disposed on the first light emitting layer EML1. The first metal pattern VL1 and the third metal pattern VL3 may overlap an edge of the first light emitting layer EML1 in a plan view. That is, the first metal pattern VL1 and the third metal pattern VL3 may cover the edge of the first light emitting layer EML1. For example, the first metal pattern VL1 and the third metal pattern VL3 may be disposed in the non-light emitting area BA adjacent to the first pixel area PX1. As illustrated in FIG. 2, the first metal pattern VL1 and the third metal pattern VL3 may be illustrated in separate configurations in a cross-sectional view. However, in a plan view, the first metal pattern VL1 and the third metal pattern VL3 may be connected to each other and form a single configuration. For example, the first metal pattern VL1 and the third metal pattern VL3 may be understood as one configuration covering entire edge of the first light emitting layer EML1 in a plan view. However, disclosure is not limited thereto, and the first metal pattern VL1 and the third metal pattern VL3 may be separate configurations.

The fifth metal pattern VL5 and the seventh metal pattern VL7 may be disposed on the second light emitting layer EML2. The fifth metal pattern VL5 and the seventh metal pattern VL7 may overlap an edge of the second light emitting layer EML2 in a plan view. That is, the fifth metal pattern VL5 and the seventh metal pattern VL7 may cover the edge of the second light emitting layer EML2. For example, the fifth metal pattern VL5 and the seventh metal pattern VL7 may be disposed in the non-light emitting area BA adjacent to the second pixel area PX2. As illustrated in FIG. 2, the fifth metal pattern VL5 and the seventh metal pattern VL7 may be illustrated in separate configurations in cross-sectional view. However, in a plan view, it may be understood that the fifth metal pattern VL5 and the seventh metal pattern VL7 are connected to each other and form a single configuration. For example, the fifth metal pattern VL5 and the seventh metal pattern VL7 may be understood as one configuration covering entire edge of the second light emitting layer EML2 in a plan view. However, this disclosure is not limited thereto, and the fifth metal pattern VL5 and the seventh metal pattern VL7 may be separate configurations.

For example, each of the first metal pattern VL1, the third metal pattern VL3, the fifth metal pattern VL5, and the seventh metal pattern VL7 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In some aspects, examples of the metal nitride may include aluminum nitride (“AlNₓ”), tungsten nitride (“WNₓ”), chromium nitride (“CrNₓ”), and/or the like. These materials may be used alone or in combination with each other. Preferably, each of the first metal pattern VL1, the third metal pattern VL3, the fifth metal pattern VL5, and the seventh metal pattern VL7 may include aluminum (“Al”).

The second metal pattern VL2 and the fourth metal pattern VL4 may be disposed on the first metal pattern VL1 and the third metal pattern VL3, respectively. For example, the second metal pattern VL2 may at least partially overlap the first metal pattern VL1 in a plan view, and the fourth metal pattern VL4 may at least partially overlap the third metal pattern VL3 in a plan view. For example, the second metal pattern VL2 and the fourth metal pattern VL4 may be disposed in the non-light emitting area BA adjacent to the first pixel area PX1. As illustrated in FIG. 2, the second metal pattern VL2 and the fourth metal pattern VL4 may be illustrated in separate configurations in cross-sectional view. However, in a plan view, the second metal pattern VL2 and the fourth metal pattern VL4 may be connected to each other and form a single configuration. For example, the second metal pattern VL2 and the fourth metal pattern VL4 may be understood as one configuration covering entire upper surfaces of the first metal pattern VL1 and the third metal pattern VL3 in a plan view. However, this disclosure is not limited thereto, and the second metal pattern VL2 and the fourth metal pattern VL4 may be separate configurations.

The sixth metal pattern VL6 and the eighth metal pattern VL8 may be disposed on the fifth metal pattern VL5 and the seventh metal pattern VL7, respectively. For example, the sixth metal pattern VL6 may at least partially overlap the fifth metal pattern VL5 in a plan view, and the eighth metal pattern VL8 may at least partially overlap the seventh metal pattern VL7 in a plan view. For example, the sixth metal pattern VL6 and the eighth metal pattern VL8 may be disposed in the non-light emitting area BA adjacent to the second pixel area PX2. As illustrated in FIG. 2, the sixth metal pattern VL6 and the eighth metal pattern VL8 may be illustrated in separate configurations in cross-sectional view. However, in a plan view, it may be understood that the sixth metal pattern VL6 and the eighth metal pattern VL8 are connected to each other and form a single configuration. For example, the sixth metal pattern VL6 and the eighth metal pattern VL8 may be understood as one configuration covering entire upper surfaces of the fifth metal pattern VL5 and the seventh metal pattern VL7 in a plan view. However, this disclosure is not limited thereto, and the sixth metal pattern VL6 and the eighth metal pattern VL8 may be separate configurations.

For example, each of the second metal pattern VL2, the fourth metal pattern VL4, the sixth metal pattern VL6, and the eighth metal pattern VL8 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other. Preferably, each of the second metal pattern VL2, the fourth metal pattern VL4, the sixth metal pattern VL6, and the eighth metal pattern VL8 may include titanium (“Ti”). In an embodiment, each of the second metal pattern VL2, the fourth metal pattern VL4, the sixth metal pattern VL6, and the eighth metal pattern VL8 may include material different from material of the first metal pattern VL1, the third metal pattern VL3, the fifth metal pattern VL5, and the seventh metal pattern VL7.

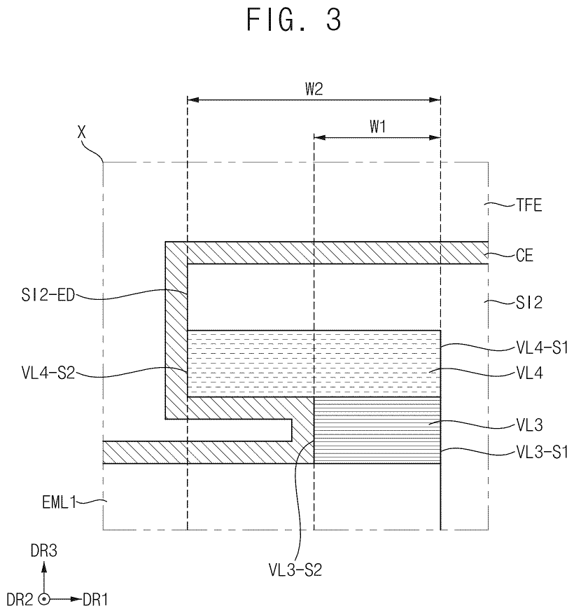

Each of the first metal pattern VL1 and the third metal pattern VL3 may include a side surface and another side surface opposite to the side surface in a cross-sectional view. The other side surface of each of the first metal pattern VL1 and the third metal pattern VL3 may be a surface facing the first pixel area PX1. For example, the other side surface of each of the first metal pattern VL1 and the third metal pattern VL3 may be a surface contacting the common electrode CE to be described later. For example, the third metal pattern VL3 may include a side surface (e.g., a side surface VL3-S1 of FIG. 3) and other side surface (e.g., other side surface VL3-S2 of FIG. 3).

Each of the fifth metal pattern VL5 and the seventh metal pattern VL7 may include a side surface and another side surface opposite to the side surface in a cross-sectional view. The other side surface of each of the fifth metal pattern VL5 and the seventh metal pattern VL7 may be a surface facing the second pixel area PX2. For example, the other side surface of each of the fifth metal pattern VL5 and the seventh metal pattern VL7 may be a surface contacting the common electrode CE.

Each of the second metal pattern VL2 and the fourth metal pattern VL4 may include a side surface and another side surface opposite to the side surface in a cross-sectional view. The other side surface of each of the second metal pattern VL2 and the fourth metal pattern VL4 may be a surface facing the first pixel area PX1. For example, the other side surface of each of the second metal pattern VL2 and the fourth metal pattern VL4 may be a surface contacting the common electrode CE. For example, the fourth metal pattern VL4 may include a side surface (e.g., a side surface VL4-S1 of FIG. 3) and other side surface (e.g., VL4-S2 of FIG. 3).

Each of the sixth metal pattern VL6 and the eighth metal pattern VL8 may include a side surface and another side surface opposite to the side surface in a cross-sectional view. The other side surface of each of the sixth metal pattern VL6 and the eighth metal pattern VL8 may be a surface facing the second pixel area PX2. For example, the other side surface of each of the sixth metal pattern VL6 and the eighth metal pattern VL8 may be a surface contacting the common electrode CE.

In an embodiment, the display device DD may further include side insulating layers SI1, SI2 and SI3. The side insulating layers SI1, SI2, and SI3 may be disposed in the non-light emitting area BA.

The first side insulating layer SI1 may cover at least a portion of each of the first pixel electrode PE1, the first light emitting layer EML1, the first metal pattern VL1, and the second metal pattern VL2. For example, the first side insulating layer SI1 may cover a portion of an upper surface and a side surface of the first pixel electrode PE1. In some aspects, the first side insulating layer SI1 may cover a side surface of the first light emitting layer EML1. In some aspects, the first side insulating layer SI1 may cover the side surface of the first metal pattern VL1 and the side surface of the second metal pattern VL2. In some aspects, the first side insulating layer SI1 may cover an upper surface of the second metal pattern VL2.

The second side insulating layer SI2 may cover at least a portion of each of the first pixel electrode PE1, the first light emitting layer EML1, the third metal pattern VL3, and the fourth metal pattern VL4. For example, the second side insulating layer SI2 may cover a portion of an upper surface and a side surface of the first pixel electrode PE1. In some aspects, the second side insulating layer SI2 may cover a side surface of the first light emitting layer EML1. In some aspects, the second side insulating layer SI2 may cover the side surface of the third metal pattern VL3 and the side surface of the fourth metal pattern VL4. In some aspects, the second side insulating layer SI2 may cover an upper surface of the fourth metal pattern VL4.

In an embodiment, the second side insulating layer SI2 may extend from one end of the first pixel area PX1 to one end of the second pixel area PX2 in a cross-sectional view. For example, the second side insulating layer SI2 may extend from the first light emitting layer EML1 to the second light emitting layer EML2. The second side insulating layer SI2 may cover at least a portion of each of the second pixel electrode PE2, the second light emitting layer EML2, the fifth metal pattern VL5 and the sixth metal pattern VL6. For example, the second side insulating layer SI2 may cover a portion of an upper surface and a side surface of the second pixel electrode PE2. In some aspects, the second side insulating layer SI2 may cover a side surface of the second light emitting layer EML2. In some aspects, the second side insulating layer SI2 may cover the side surface of the fifth metal pattern VL5 and the side surface of the sixth metal pattern VL6. In some aspects, the second side insulating layer SI2 may cover an upper surface of the sixth metal pattern VL6.

The third side insulating layer SI3 may cover at least a portion of each of the second pixel electrode PE2, the second light emitting layer EML2, the seventh metal pattern VL7, and the eighth metal pattern VL8. For example, the third side insulating layer SI3 may cover a portion of an upper surface and a side surface of the second pixel electrode PE2. In some aspects, the third side insulating layer SI3 may cover a side surface of the second light emitting layer EML2. In some aspects, the third side insulating layer SI3 may cover the side surface of the seventh metal pattern VL7 and the side surface of the eighth metal pattern VL8. In some aspects, the third side insulating layer SI3 may cover an upper surface of the eighth metal pattern VL8.

As illustrated in FIG. 2, the first side insulating layer SI1, the second side insulating layer SI2, and the third side insulating layer SI3 may be illustrated as separate configurations in cross-sectional view. However, in a plan view, it may be understood that the first side insulating layer SI1, the second side insulating layer SI2, and the third side insulating layer SI3 are connected to each other and form a single configuration. For example, the first side insulating layer SI1, the second side insulating layer SI2, and the third side insulating layer SI3 may be understood as one configuration surrounding the plurality of pixel areas in a plan view. However, this disclosure is not limited thereto, and the first side insulating layer SI1, the second side insulating layer SI2, and the third side insulating layer SI3 may be separate configurations.

The first side insulating layer SI1 may include an inner side surface in a cross-sectional view. The inner side surface of the first side insulating layer SI1 may be a surface in contact with the first pixel area PX1 in a plan view. The second side insulating layer SI2 may have a first inner side surface (e.g., a first inner side surface SI2-ED of FIG. 3) in a cross-sectional view. The first inner side surface of the second side insulating layer SI2 may be a surface in contact with the first pixel area PX1 in a plan view. As described herein, in a plan view, the first side insulating layer SI1, the second side insulating layer SI2, and the third side insulating layer SI3 may be connected to each other and form a single configuration. That is, the first side insulating layer SI1, the second side insulating layer SI2, and the third side insulating layer SI3 may form one side insulating layer. The side insulating layer may define a first opening in the first pixel area PX1. The inner side surface of the first side insulating layer SI1 and the first inner side surface of the second side insulating layer SI2 may be in contact with the first opening.

The second side insulating layer SI2 may have a second inner side surface in a cross-sectional view. The second inner side surface of the second side insulating layer SI2 may be a surface in contact with the second pixel area PX2 in a plan view. The third side insulating layer SI3 may have an inner side surface in a cross-sectional view. The inner side surface of the third side insulating layer SI3 may be a surface in contact with the second pixel area PX2 in a plan view. As described herein, the first side insulating layer SI1, the second side insulating layer SI2, and the third side insulating layer SI3 may form one side insulating layer, and the side insulating layer may define a second opening in the second pixel area PX2. The second inner side surface of the second side insulating layer SI2 and the inner side surface of the third side insulating layer SI3 may be in contact with the second opening.

As the display device DD includes the first side insulating layer SI1, the second side insulating layer SI2, and the third side insulating layer SI3, side surfaces of the first light emitting layer EML1 and the second light emitting layer EML2 may be protected. In some aspects, the first side insulating layer SI1 and the second side insulating layer may prevent the first pixel electrode PE1 and the common electrode CE from being in contact with each other. Therefore, the first side insulating layer SI1 and the second side insulating layer SI2 may prevent leakage current from flowing between the first pixel electrode PE1 and the common electrode CE. The second side insulating layer SI2 and the third side insulating layer SI3 may prevent the second pixel electrode PE2 and the common electrode CE from being in contact with each other. Therefore, the second side insulating layer SI2 and the third side insulating layer SI3 may prevent leakage current from flowing between the second pixel electrode PE2 and the common electrode CE.

For example, each of the first side insulating layer SI1, the second side insulating layer SI2, and the third side insulating layer SI3 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The common electrode CE may be disposed on the first light emitting layer EML1 and the second light emitting layer EML2. In an embodiment, the common electrode CE may cover at least a portion of each of the first light emitting layer EML1, the first metal pattern VL1, the second metal pattern VL2, the third metal pattern VL3, the fourth metal pattern VL4, the first side insulating layer SI1, and the second side insulating layer SI2. For example, the common electrode CE may cover a portion of an upper surface of the first light emitting layer EML1. In some aspects, the common electrode CE may cover the other side surfaces of the first metal pattern VL1 and the third metal pattern VL3. In some aspects, the common electrode CE may cover the other side surfaces of the second metal pattern VL2 and the fourth metal pattern VL4. In some aspects, the common electrode CE may cover the inner side surface of the first side insulating layer SI1 and the first inner side surface of the second side insulating layer SI2. The common electrode CE may entirely cover the first side insulating layer SI1 and the second side insulating layer SI2.

In an embodiment, the common electrode CE may be continuously disposed over the first pixel area PX1, the non-light emitting area BA, and the second pixel area PX2. In an embodiment, the common electrode CE may cover at least a portion of each of the second light emitting layer EML2, the fifth metal pattern VL5, the sixth metal pattern VL6, the seventh metal pattern VL7, the eighth metal pattern VL8, the second side insulating layer SI2, and the third side insulating layer SI3. For example, the common electrode CE may cover a portion of an upper surface of the second light emitting layer EML2. In some aspects, the common electrode CE may cover the other side surfaces of the fifth metal pattern VL5 and the seventh metal pattern VL7. In some aspects, the common electrode CE may cover the other side surfaces of the sixth metal pattern VL6 and the eighth metal pattern VL8. In some aspects, the common electrode CE may cover the second inner side surface of the second side insulating layer SI2 and the inner side surface of the third side insulating layer SI3. The common electrode CE may entirely cover the third side insulating layer SI3.

The common electrode CE may include a metal, an alloy, a metal nitride, a conductive metal oxide, a transparent conductive material, and/or the like. These materials may be used alone or in combination with each other. The common electrode CE may operate as a cathode. In an embodiment, the common electrode CE may be referred to as a second electrode.

The encapsulation layer TFE may be disposed on the common electrode CE. The encapsulation layer TFE may prevent impurities, moisture, and/or the like from penetrating into the first pixel electrode PE1, the second pixel electrode PE2, the first light emitting layer EML1, the second light emitting layer EML2, and the common electrode CE from an outside. The encapsulation layer TFE may include at least one inorganic layer and at least one organic layer.

For example, the inorganic layer may include silicon oxide, silicon nitride, silicon oxynitride, and/or the like. These materials may be used alone or in combination with each other. The organic layer may include a cured polymer such as, for example, polyacrylate.

FIG. 3 is an enlarged cross-sectional view of area A of FIG. 2.

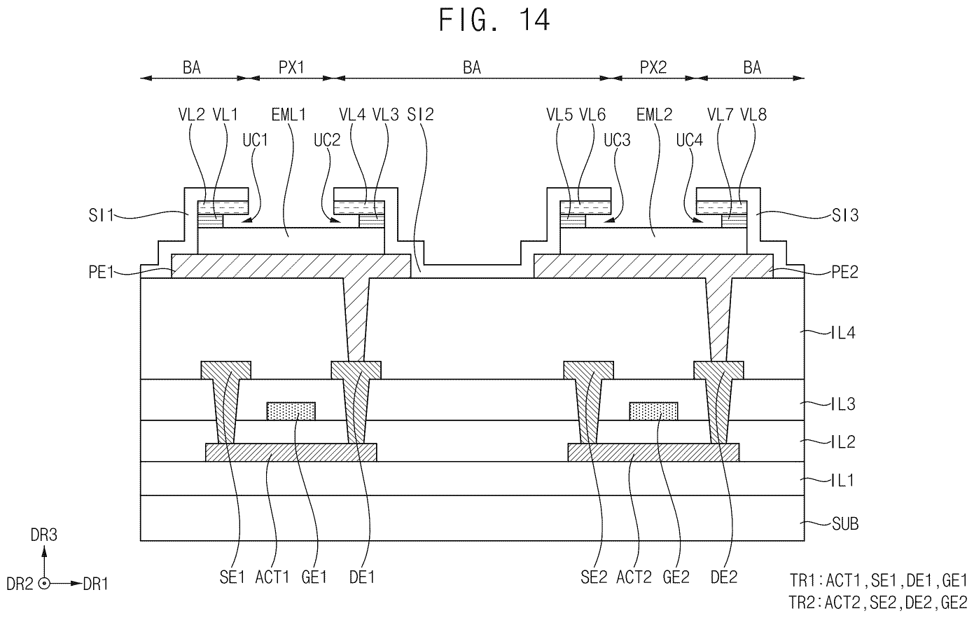

Referring to FIGS. 2 and 3, the fourth metal pattern VL4 may further protrude than the third metal pattern VL3. For example, the fourth metal pattern VL4 may further protrude toward the center of the first pixel area PX1 than the third metal pattern VL3. For example, as illustrated in FIG. 3, the fourth metal pattern VL4 may further protrude in a direction opposite to the first direction DR1 in a cross-sectional view, compared to the third metal pattern VL3. Accordingly, an undercut area (e.g., a second undercut area UC2 of FIG. 14) may be formed on the first light emitting layer EML1. That is, as width W2 of the fourth metal pattern VL4 in the first direction DR1 is greater than the width W1 of the third metal pattern VL3 in the first direction DR1, the undercut area may be defined on the first light emitting layer EML1.

As described herein, the third metal pattern VL3 may include the side surface VL3-S1 and the other side surface VL3-S2. The fourth metal pattern VL4 may include the side surface VL4-S1 and the other side surface VL4-S2. The second side insulating layer SI2 may include the first inner side surface SI2-ED.

In an embodiment, the first inner side surface SI2-ED of the second side insulating layer SI2 and the other side surface VL4-S2 of the fourth metal pattern VL4 may be disposed on substantially a same plane. That is, the first inner side surface SI2-ED of the second side insulating layer SI2 may be a surface extending from the other side surface VL4-S2 of the fourth metal pattern VL4. For example, the first inner side surface SI2-ED of the second side insulating layer SI2 may be a surface extending in the third direction DR3 from the other side surface VL4-S2 of the fourth metal pattern VL4. That is, the first inner side surface SI2-ED of the second side insulating layer SI2 and the other side surface VL4-S2 of the fourth metal pattern VL4 may be disposed on one plane formed by the second direction DR2 and the third direction DR3. Accordingly, the common electrode CE may be in electrical contact with the fourth metal pattern VL4 without being disconnected. That is, the common electrode CE may be in electrical contact with the fourth metal pattern VL4 without being disconnected around a portion where the second side insulating layer SI2 and the fourth metal pattern VL4 are in contact with each other. For example, the common electrode CE may have a relatively small thickness of about 100 angstroms, and accordingly, resistance of the common electrode CE may be large. According to an embodiment, as the common electrode CE is not disconnected and is in electrical contact with the fourth metal pattern VL4, resistance of the common electrode CE may be reduced.

In some aspects, the common electrode CE may be disposed in the undercut area (e.g., the second undercut area UC2 of FIG. 14). For example, the common electrode CE may be in contact with a lower surface of the fourth metal pattern VL4 and the other side surface VL3-S2 of the third metal pattern VL3 in the undercut area. As the undercut area is formed on the first light emitting layer EML1, a contact area between the common electrode CE and the fourth metal pattern VL4 may increase. Therefore, resistance of the common electrode CE may decrease.

The third metal pattern VL3 and the fourth metal pattern VL4 may be understood as forming a single metal pattern. For example, the third metal pattern VL3 may be referred to as a first portion of the metal pattern, and the fourth metal pattern VL4 may be referred to as a second portion of the metal pattern.

Although the third metal pattern VL3, the fourth metal pattern VL4, and the second side insulating layer SI2 have been mainly described with reference to FIGS. 2 and 3, the first metal pattern VL1, the fifth metal pattern VL5, and the seventh metal pattern VL7 may have substantially the same structure as the third metal pattern VL3, the second metal pattern VL2, the sixth metal pattern VL6, and the eighth metal pattern VL8 may have substantially the same structure as the fourth metal pattern VL4, and the first side insulating layer SI1 and the third side insulating layer SI3 may have substantially the same structure as the second side insulating layer SI2.

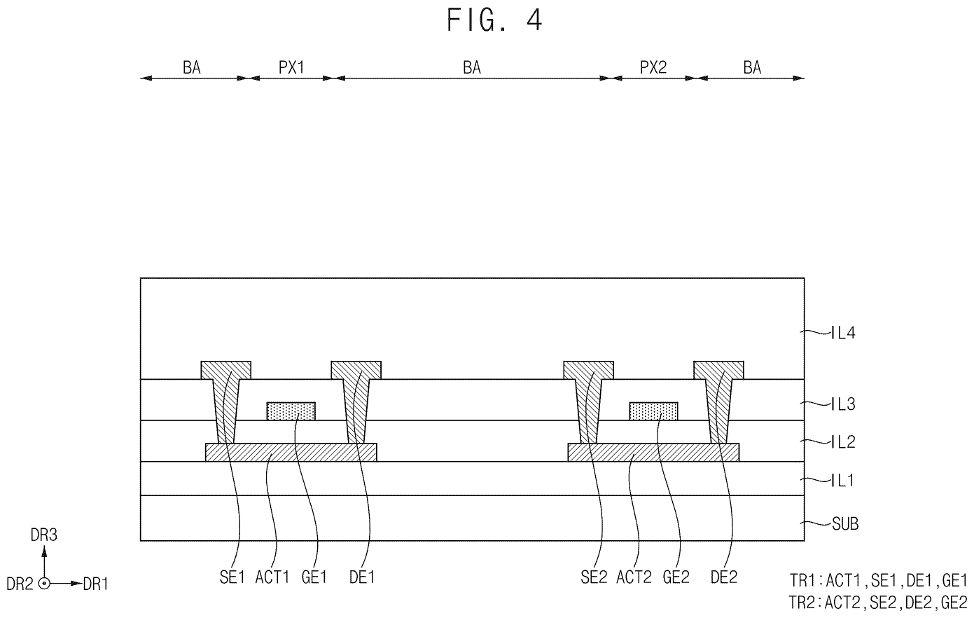

FIGS. 4, 5, 6, 7, 8, 9, 10, 11, 12, 13, 14, and 15 are cross-sectional views illustrating a method of manufacturing the display device of FIG. 2.

In the descriptions of the method and processes herein, the operations may be performed in a different order than the order shown and/or described, or the operations may be performed in different orders or at different times. Certain operations may also be left out of the method and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

The method may include forming the first insulating layer IL1 on the substrate SUB. In an embodiment, the substrate SUB may include a transparent material or an opaque material. The substrate SUB may be formed of a transparent resin substrate. An example of the transparent resin substrate may include a polyimide substrate. In this case, for example, the polyimide substrate may include a first organic layer, a first barrier layer, a second organic layer, and the like. Alternatively, the substrate SUB may include a quartz substrate (e.g. a synthetic quartz substrate, a fluorine-doped quartz substrate), a calcium fluoride substrate, a sodalime glass substrate, a non-alkali glass substrate, or the like. These materials may be used alone or in combination with each other.

The first insulating layer IL1 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The method may include forming the first active pattern ACT1 and the second active pattern ACT2 on the first insulating layer IL1. For example, the first active pattern ACT1 may be formed in at least a portion of the first pixel area PX1, and the second active pattern ACT2 may be formed in at least a portion of the second pixel area PX2.

In an example, each of the first active pattern ACT1 and the second active pattern ACT2 may include an inorganic semiconductor (e.g., amorphous silicon, poly silicon, metal oxide semiconductor), an organic semiconductor, and/or the like. These materials may be used alone or in combination with each other. Each of the first active pattern ACT1 and the second active pattern ACT2 may include a source area, a drain area, and a channel area disposed between the source area and the drain area.

The method may include forming the second insulating layer IL2 on the first insulating layer IL1. The second insulating layer IL2 may be formed such that the second insulating layer IL2 sufficiently covers the first active pattern ACTI and the second active pattern ACT2.

For example, the second insulating layer IL2 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The method may include forming the first gate electrode GE1 and the second gate electrode GE2 on the second insulating layer IL2. The first gate electrode GE1 may be formed such that the first gate electrode GE1 overlaps the channel area of the first active pattern ACT1 in a plan view. The second gate electrode GE2 may be formed such that the second gate electrode GE2 overlaps the channel area of the second active pattern ACT2 in a plan view.

Each of the first gate electrode GE1 and the second gate electrode GE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium

(“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

The method may include forming the third insulating layer IL3 on the second insulating layer IL2. The third insulating layer IL3 may be formed such that the third insulating layer IL3 sufficiently covers the first gate electrode GE1 and the second gate electrode GE2.

For example, the third insulating layer IL3 may include inorganic materials such as, for example, silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The method may include forming the first contact electrode SE1, the second contact electrode DE1, the third contact electrode SE2 and the fourth contact electrode DE2 on the third insulating layer IL3. The method may include forming the first contact hole defining through the second insulating layer IL2 and the third insulating layer IL3 such that the first contact electrode SE1 may be connected to the source area of the first active pattern ACT1. The method may include forming the second contact hole defining through the second insulating layer IL2 and the third insulating layer IL3 such that the second contact electrode DE1 may be connected to the drain area of the first active pattern ACT1. The method may include forming the third contact hole defining through the second insulating layer IL2 and the third insulating layer IL3 such that the third contact electrode SE2 may be connected to the source area of the second active pattern ACT2. The method may include forming the fourth contact hole defining through the second insulating layer IL2 and the third insulating layer IL3 such that the fourth contact electrode DE2 may be connected to the drain area of the second active pattern ACT2.

For example, each of the first contact electrode SE1, the second contact electrode DE1, the third contact electrode SE2 and the fourth contact electrode DE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other.

The method may include forming the fourth insulating layer IL4 on the third insulating layer IL3. The fourth insulating layer IL4 may be formed such that the fourth insulating layer IL4 sufficiently covers the first contact electrode SE1, the second contact electrode DE1, the third contact electrode SE2 and the fourth contact electrode DE2.

In an embodiment, the fourth insulating layer IL4 may include an organic material. For example, the fourth insulating layer IL4 may include an organic material such as, for example, a phenolic resin, an acrylic resin, a polyimide resin, a polyamide resin, a siloxane resin, an epoxy resin, and/or the like. These materials may be used alone or in combination with each other.

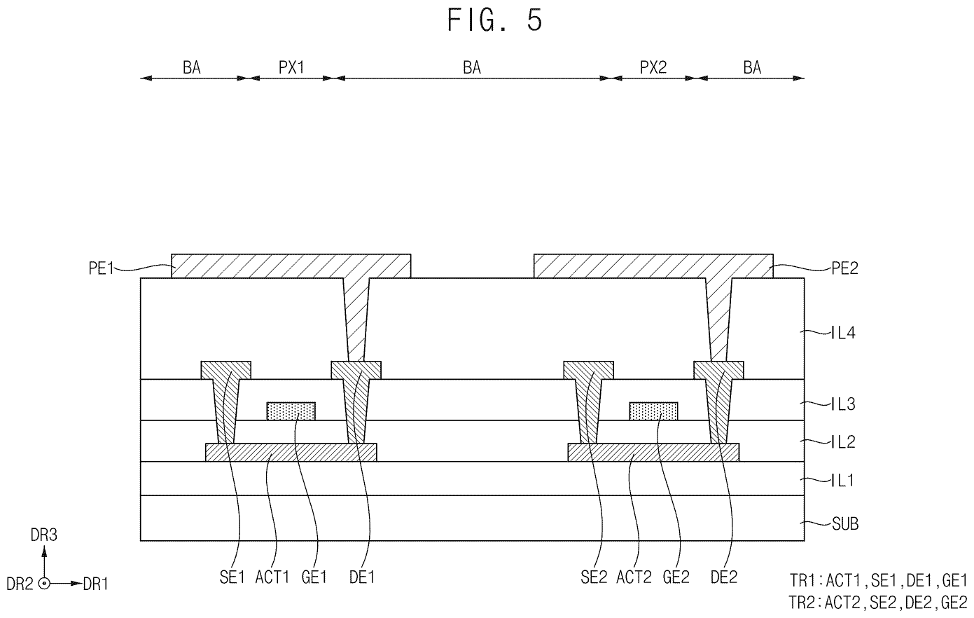

Referring to FIG. 5, the method may include forming the first pixel electrode PE1 and the second pixel electrode PE2 on the fourth insulating layer IL4. The first pixel electrode PE1 may be formed in the first pixel area PX1. In an embodiment, the first pixel electrode PE1 may be formed in at least a portion of the non-light emitting area BA and in the first pixel area PX1. The second pixel electrode PE2 may be formed in the second pixel area PX2. In an embodiment, the second pixel electrode PE2 may be formed in at least a portion of the non-light emitting area BA and in the second pixel area PX2.

For example, the method may include forming the first pixel electrode PE1 and the second pixel electrode PE2 by forming a preliminary pixel electrode on the fourth insulating layer IL4 and removing a portion of the preliminary pixel electrode. In some aspects, the method may include forming the fifth contact hole defining through the fourth insulating layer IL4 such that the first pixel electrode PE1 may be connected to the second contact electrode DE1. In some aspects, the method may include forming the sixth contact hole defining through the fourth insulating layer IL4 such that the second pixel electrode PE2 may be connected to the fourth contact electrode DE2.

Each of the first pixel electrode PE1 and the second pixel electrode PE2 may include a metal, an alloy, a metal nitride, a conductive metal oxide, a transparent conductive material, and/or the like. These materials may be used alone or in combination with each other. In an embodiment, each of the first pixel electrode PE1 and the second pixel electrode PE2 may have a stacked structure including ITO/Ag/ITO. In an embodiment, the first pixel electrode PE1 may be referred to as a first electrode, and the second pixel electrode PE2 may be referred to as a third electrode.

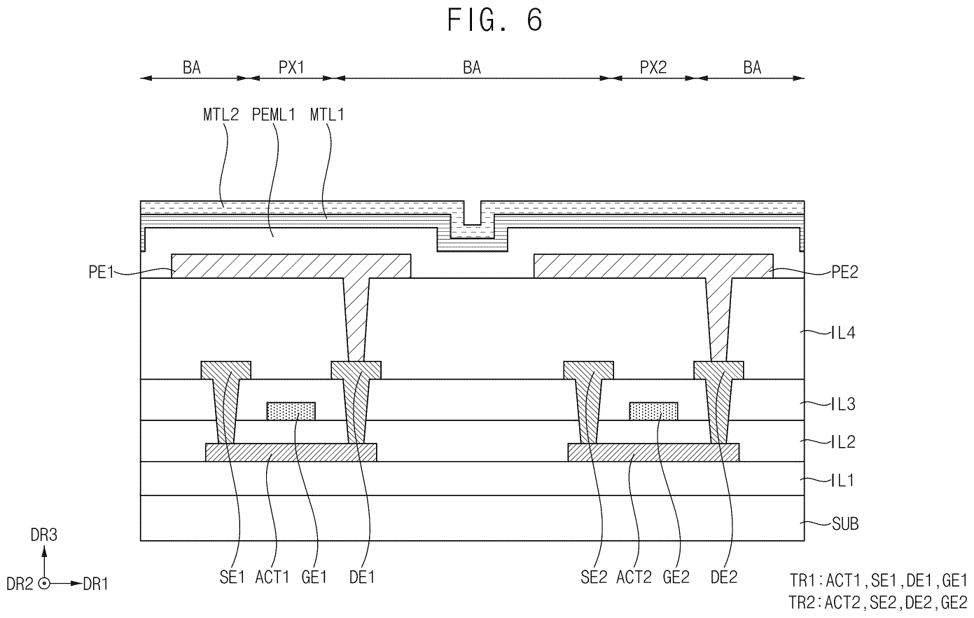

Referring to FIG. 6, the method may include forming a first preliminary light emitting layer PEML1 on the fourth insulating layer IL4. The first preliminary light emitting layer PEML1 may be formed such that the first preliminary light emitting layer PEML1 covers the first pixel electrode PE1 and the second pixel electrode PE2.

For example, the first preliminary light emitting layer PEML1 may include a first functional layer including an organic material, an intermediate layer including a light emitting material and disposed on the first functional layer, and a second functional layer including an organic material and disposed on the intermediate layer. For example, the first functional layer may include a hole injection layer, a hole transport layer, and/or the like, and the second functional layer may include an electron transport layer, an electron injection layer, and/or the like.

The method may include forming a first metal layer MTL1 on the first preliminary light emitting layer PEML1. For example, the first metal layer MTL1 may be formed such that the first metal layer MTL1 entirely covers the first preliminary light emitting layer PEML1.

For example, the first metal layer MTL1 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In some aspects, examples of the metal nitride may include aluminum nitride (“AlNₓ”), tungsten nitride (“WNₓ”), chromium nitride (“CrNₓ”), and/or the like. These materials may be used alone or in combination with each other. Preferably, the first metal layer MTL1 may include aluminum (“Al”).

The method may include forming a second metal layer MTL2 on the first metal layer MTL1. For example, the second metal layer MTL2 may be formed such that the second metal layer MTL2 entirely covers the first metal layer MTL1.

For example, the second metal layer MTL2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other. Preferably, the second metal layer MTL2 may include titanium (“Ti”).

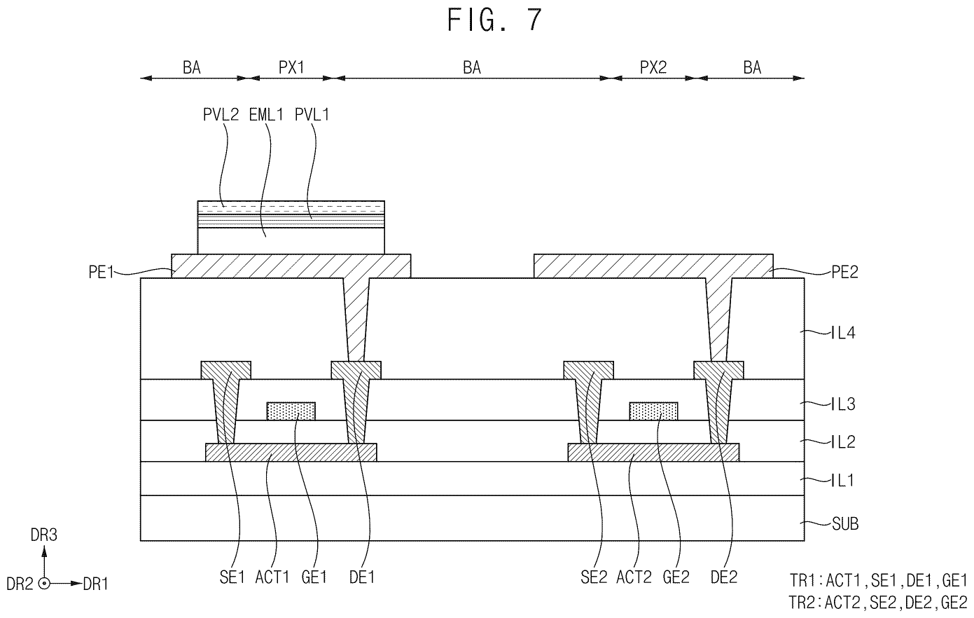

Referring to FIGS. 6 and 7, the method may include removing a portion of the first preliminary light emitting layer PEML1, a portion of the first metal layer MTL1, and a portion of the second metal layer MTL2. Accordingly, the first light emitting layer EML1, a first preliminary metal pattern PVL1, and a second preliminary metal pattern PVL2 may be formed. In an embodiment, the portion of the first preliminary light emitting layer PEML1, the portion of the first metal layer MLT1, and the portion of the second metal layer MTL2 may be simultaneously removed. For example, the portion of the first preliminary light emitting layer PEML1, the portion of the first metal layer MLT1, and the portion of the second metal layer MTL2 may be simultaneously removed by a dry etching process. However, this disclosure is not limited thereto, and in an embodiment, the portion of the first preliminary light emitting layer PEML1, the portion of the first metal layer MLT1, and the portion of the second metal layer MTL2 may not be simultaneously removed.

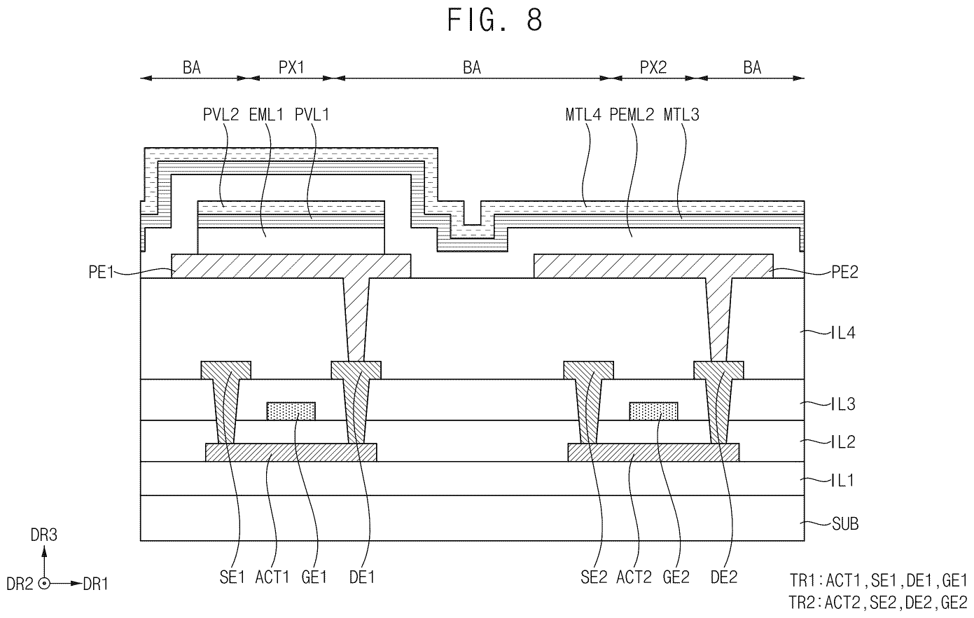

Referring to FIG. 8, the method may include forming a second preliminary light emitting layer PEML2 on the fourth insulating layer IL4. The second preliminary light emitting layer PEML2 may be formed such that the second preliminary light emitting layer PEML2 covers the first pixel electrode PE1, the second pixel electrode PE2, the first light emitting layer EML1, the first preliminary metal pattern PVL1, and the second preliminary metal pattern PVL2.

For example, the second preliminary light emitting layer PEML2 may include a first functional layer including an organic material, an intermediate layer including a light emitting material and disposed on the first functional layer, and a second functional layer including an organic material and disposed on the intermediate layer. For example, the first functional layer may include a hole injection layer, a hole transport layer, and/or the like, and the second functional layer may include an electron transport layer, an electron injection layer, and/or the like.

The method may include forming a third metal layer MTL3 on the second preliminary light emitting layer PEML2. For example, the third metal layer MTL3 may be formed such that the third metal layer MTL3 entirely covers the second preliminary light emitting layer PEML2.

For example, the third metal layer MTL3 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other. Preferably, the third metal layer MTL3 may include aluminum (“Al”).

The method may include forming a fourth metal layer MTL4 on the third metal layer MTL3. For example, the fourth metal layer MTL4 may be formed such that the fourth metal layer MTL4 entirely covers the third metal layer MTL3.

For example, the fourth metal layer MTL4 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. Examples of the metal nitride may include aluminum nitride (“AlNₓ”), tungsten nitride (“WNₓ”), chromium nitride (“CrNₓ”), and/or the like. These materials may be used alone or in combination with each other. Preferably, the third metal layer MTL3 may include aluminum (“Al”). Preferably, the fourth metal layer MTL4 may include titanium (“Ti”).

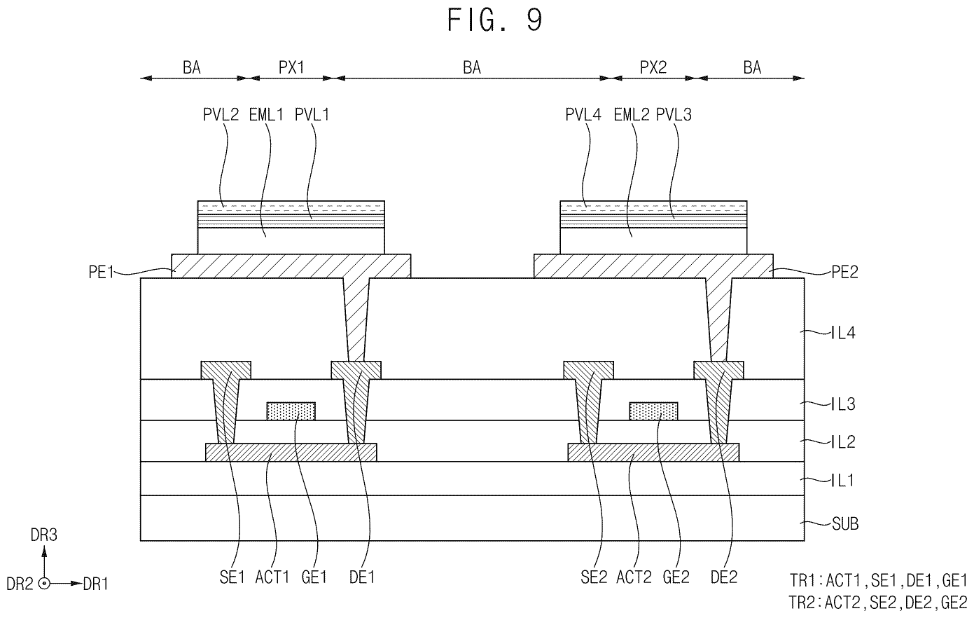

Referring to FIGS. 8 and 9, the method may include removing a portion of the second preliminary light emitting layer PEML2, a portion of the third metal layer MTL3, and a portion of the fourth metal layer MTL4. Accordingly, the second light emitting layer EML2, a third preliminary metal pattern PVL3, and a fourth preliminary metal pattern PVL4 may be formed. In an embodiment, the portion of the second preliminary light emitting layer PEML2, the portion of the third metal layer MLT3, and the portion of the fourth metal layer MTL4 may be simultaneously removed. For example, the portion of the second preliminary light emitting layer PEML2, the portion of the third metal layer MLT3, and the portion of the fourth metal layer MTL4 may be simultaneously removed by a dry etching process. However, this disclosure is not limited thereto, and in an embodiment, the portion of the second preliminary light emitting layer PEML2, the portion of the third metal layer MLT3, and the portion of the fourth metal layer MTL4 may not be simultaneously removed.

The method may include forming the first light emitting layer EML1, the first preliminary metal pattern PVL1, and the second preliminary metal pattern PVL2 in the first pixel area PX1 and the non-light emitting area BA adjacent to the first pixel area PX1. The method may include forming the second light emitting layer EML2, the third preliminary metal pattern PVL3, and the fourth preliminary metal pattern PVL4 in the second pixel area PX2 and the non-light emitting area BA adjacent to the second pixel area PX2.

In an embodiment, the method may include forming each of the first light emitting layer EML1 and the second light emitting layer EML2 without using a metal mask or a fine metal mask (FMM). For example, the first light emitting layer EML1 and the second light emitting layer EML2 may be formed by directly patterning the first preliminary light emitting layer (e.g., the first preliminary light emitting layer PEML1 of FIG. 6) and the second preliminary light emitting layer (e.g., the second preliminary light emitting layer PEML2 of FIG. 8), respectively. However, this disclosure is not limited thereto, and in an embodiment, each of the first light emitting layer EML1 and the second light emitting layer EML2 may be formed through a metal mask or a fine metal mask.

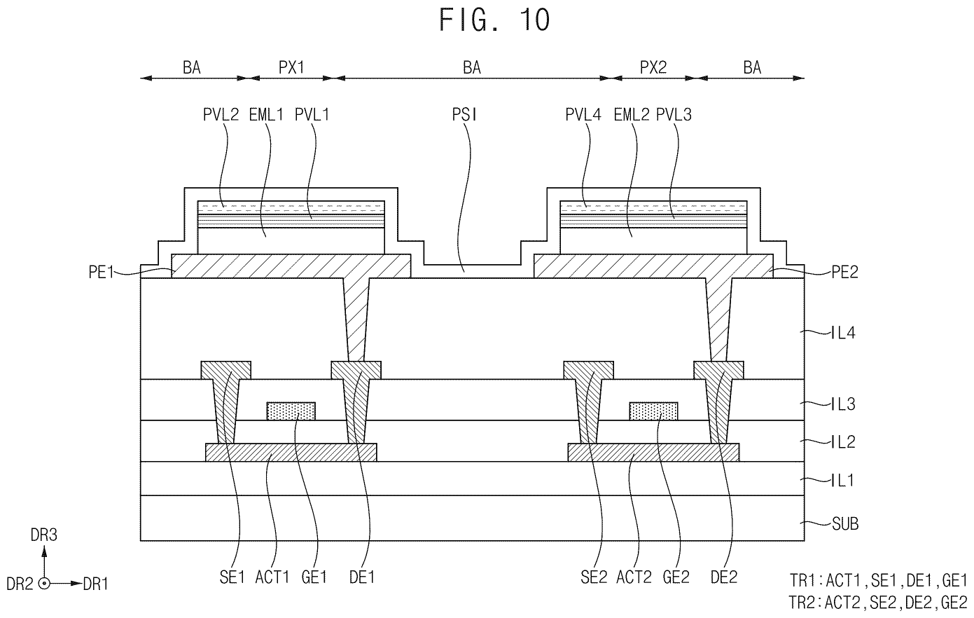

Referring to FIG. 10, the method may include forming a preliminary side insulating layer PSI on the fourth insulating layer IL4. For example, the preliminary side insulating layer PSI may be formed such that the preliminary side insulating layer PSI covers at least a portion of each of the first pixel electrode PE1, the second pixel electrode PE2, the first light emitting layer EML1, the second light emitting layer EML2, the first preliminary metal pattern PVL1, the second preliminary metal pattern PVL2, the third preliminary metal pattern PVL3, and the fourth preliminary metal pattern PVL4.

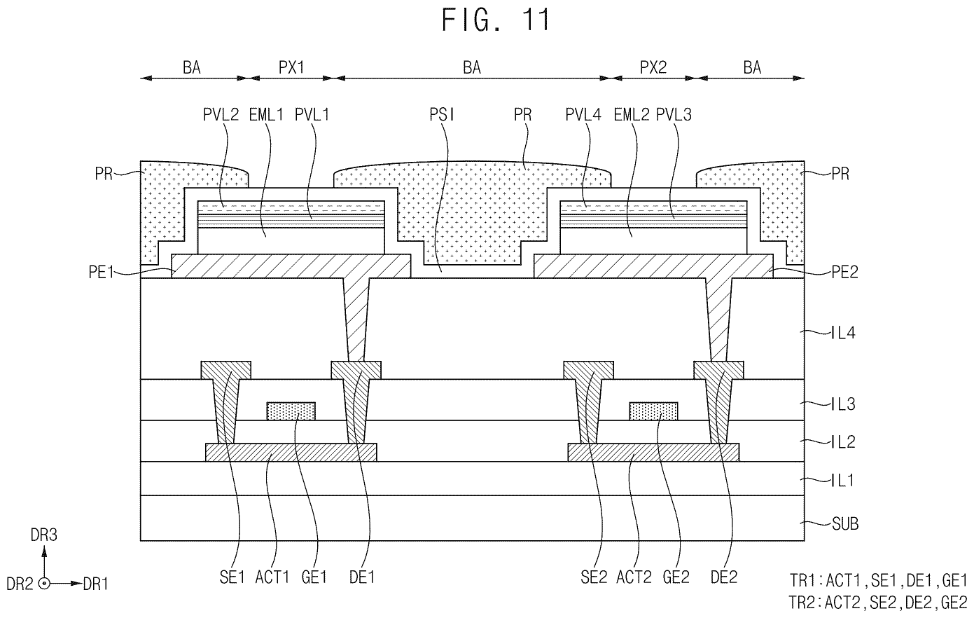

Referring to FIG. 11, the method may include forming a photoresist layer PR on the preliminary side insulating layer PSI. The method may include forming the photoresist layer PR in the non-light emitting area BA. That is, the method may include refraining from forming the photoresist layer PR in the first pixel area PX1 and the second pixel area PX2. For example, the photoresist layer PR may include an organic material.

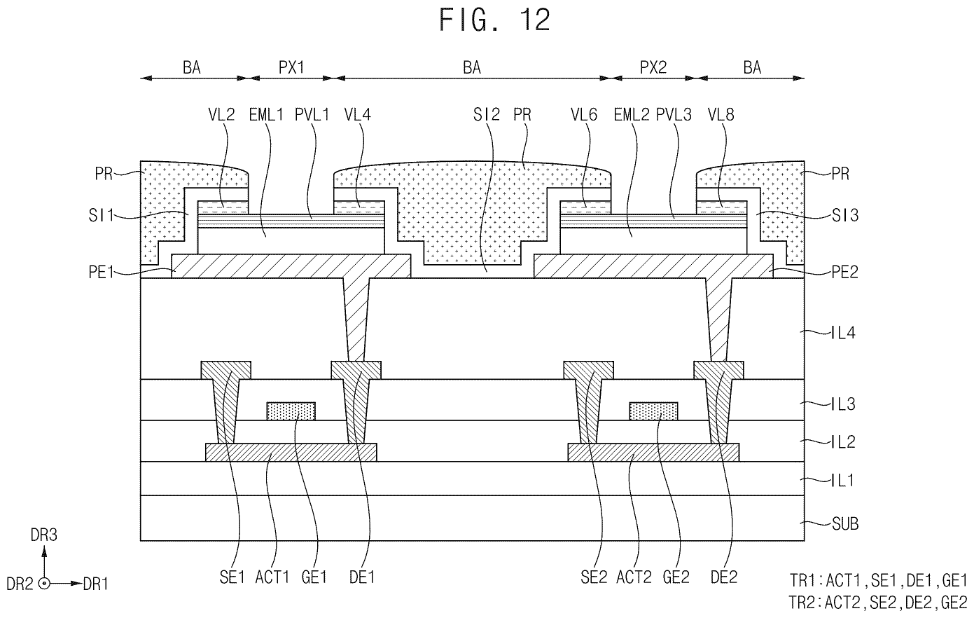

Referring to FIGS. 11 and 12, the method may include removing a portion of the preliminary side insulating layer PSI. In some aspects, the method may include removing another portion of the preliminary side insulating layer PSI. Accordingly, the first side insulating layer SI1, the second side insulating layer SI2, and the third side insulating layer SI3 may be formed. The portion and the other portion of the preliminary side insulating layer PSI may be removed by a dry etching process. The portion of the preliminary side insulating layer PSI may be a portion disposed in the first pixel area PX1, and the other portion of the preliminary side insulating layer PSI may be a portion disposed in the second pixel area PX2. In this case, for example, the photoresist layer PR may be used as a mask for dry etching.

In some aspects, the method may include forming the second metal pattern VL2 and the fourth metal pattern VL4 by removing a portion of the fourth preliminary metal pattern PVL4. For example, the portion of the second preliminary metal pattern PVL2 may be removed by a dry etching process. In this case, for example, the photoresist layer PR may be used as a mask for dry etching. The portion of the second preliminary metal pattern PVL2 may be a portion disposed in the first pixel area PX1.

In some aspects, the method may include forming the sixth metal pattern VL6 and the eighth metal pattern VL8 by removing a portion of the fourth preliminary metal pattern PVL4. For example, the portion of the fourth preliminary metal pattern PVL4 may be removed by a dry etching process. In this case, for example, the photoresist layer PR may be used as a mask for dry etching. The portion of the fourth preliminary metal pattern PVL4 may be a portion disposed in the second pixel area PX2.

In an embodiment, the method may include simultaneously removing the portion of the preliminary side insulating layer PSI and the portion of the second preliminary metal pattern PVL2. In some aspects, the method may include simultaneously removing the other portion of the preliminary side insulating layer PSI and the portion of the fourth preliminary metal pattern PVL4. Accordingly, the first side insulating layer SI1, the second side insulating layer SI2, the second metal pattern VL2 and the fourth metal pattern VL4 may be easily formed at the same time. In some aspects, the second side insulating layer SI2, the third side insulating layer SI3, the sixth metal pattern VL6, and the eighth metal pattern VL8 may be easily formed at the same time.

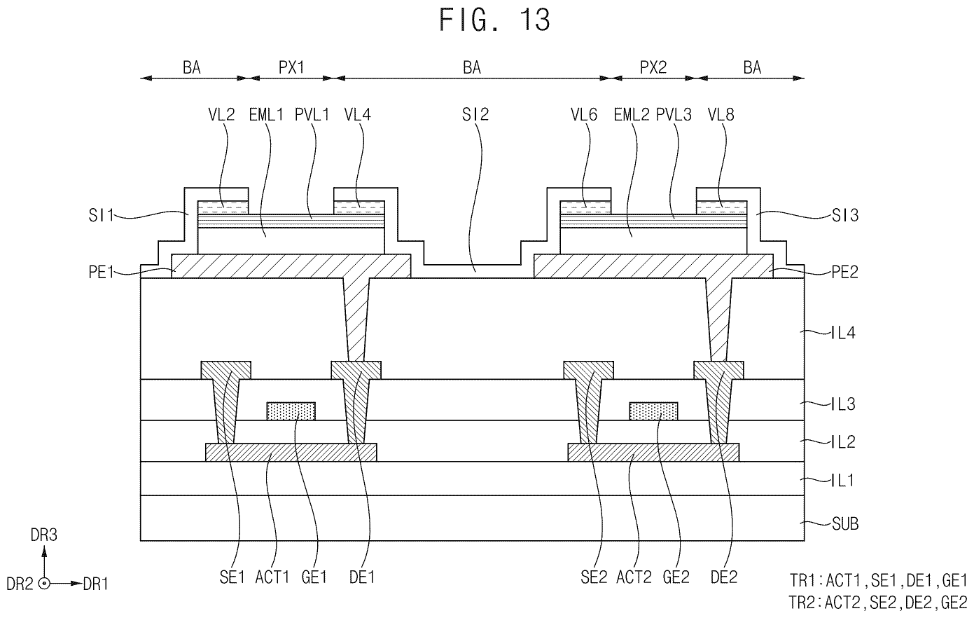

Referring to FIG. 13, the method may include removing the photoresist layer PR. For example, the photoresist layer PR may be removed by a strip process.

Referring to FIGS. 13 and 14, the method may include forming the first metal pattern VL1 and the third metal pattern VL3 by removing a portion of the first preliminary metal pattern PVL1. For example, the portion of the first preliminary metal pattern PVL1 may be removed by a wet etching process. As described herein, the second metal pattern VL2 and the fourth metal pattern VL4 may include titanium (“Ti”), and the first preliminary metal pattern PVL1 may include aluminum (“Al”). By etching selectivity, etching rate of aluminum metal layer may be greater than etching rate of titanium metal layer. Therefore, through the wet etching process, the second metal pattern VL2 and the fourth metal pattern VL4 may be hardly removed, or only a portion significantly smaller than a portion of the first preliminary metal pattern PVL1 may be removed. Accordingly, the width of the first metal pattern VL1 in the first direction DR1 may be less than the width of the second metal pattern VL2 in the first direction DR1. Accordingly, a first undercut area UC1 may be formed. In some aspects, the width of the third metal pattern VL3 in the first direction DR1 may be less than the width of the fourth metal pattern VL4 in the first direction DR1. Accordingly, a second undercut area UC2 may be formed.

In some aspects, the method may include forming the fifth metal pattern VL5 and the seventh metal pattern VL7 by removing a portion of the third preliminary metal pattern PVL3. For example, the portion of the third preliminary metal pattern PVL3 may be removed by a wet etching process. As described herein, the sixth metal pattern VL6 and the eighth metal pattern VL8 may include titanium (“Ti”), and the third preliminary metal pattern PVL3 may include aluminum (“Al”). By etching selectivity, etching rate of aluminum metal layer may be greater than etching rate of titanium metal layer. Therefore, through the wet etching process, the sixth metal pattern VL6 and the eighth metal pattern VL8 may be hardly removed, or only a portion significantly smaller than a portion of the third preliminary metal pattern PVL3 may be removed. Accordingly, the width of the fifth metal pattern VL5 in the first direction DR1 may be less than the width of the sixth metal pattern VL6 in the first direction DR1. Accordingly, a third undercut area UC3 may be formed. In some aspects, the width of the seventh metal pattern VL7 in the first direction DR1 may be less than the width of the eighth metal pattern VL8 in the first direction DR1. Accordingly, a fourth undercut area UC4 may be formed.

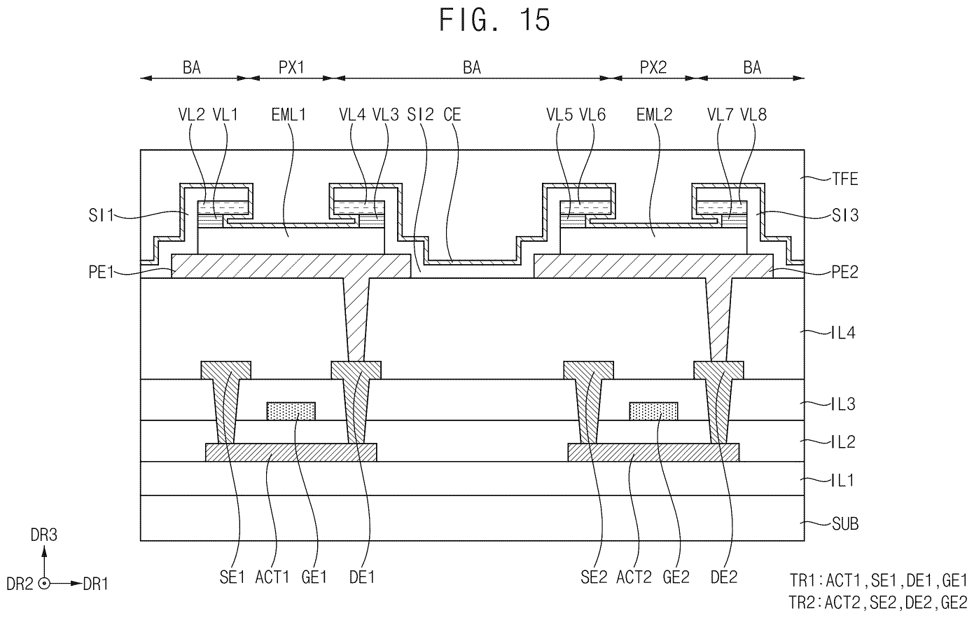

Referring to FIG. 15, the method may include forming the common electrode CE on the first light emitting layer EML1 and the second light emitting layer EML2. In an embodiment, the common electrode CE may be formed such that the common electrode CE covers at least a portion of each of the first light emitting layer EML1, the first metal pattern VL1, the second metal pattern VL2, the third metal pattern VL3, the fourth metal pattern VL4, the first side insulating layer SI1, and the second side insulating layer SI2.

In an embodiment, the method may include continuously forming the common electrode CE over the first pixel area PX1, the non-light emitting area BA, and the second pixel area PX2. In an embodiment, the common electrode CE may be formed such that the common electrode CE covers at least a portion of each of the second light emitting layer EML2, the fifth metal pattern VL5, the sixth metal pattern VL6, the seventh metal pattern VL7, the eighth metal pattern VL8, the second side insulating layer SI2, and the third side insulating layer SI3.

The common electrode CE may include a metal, an alloy, a metal nitride, a conductive metal oxide, a transparent conductive material, and/or the like. These materials may be used alone or in combination with each other. In an embodiment, the common electrode CE may be referred to as a second electrode.

The method may include forming the encapsulation layer TFE on the common electrode CE. The encapsulation layer TFE may prevent impurities, moisture, and/or the like from penetrating into the first pixel electrode PE1, the second pixel electrode PE2, the first light emitting layer EML1, the second light emitting layer EML2, and the common electrode CE from an outside. The encapsulation layer TFE may include at least one inorganic layer and at least one organic layer.

For example, the inorganic layer may include silicon oxide, silicon nitride, silicon oxynitride, or the like. These may be used alone or in combination with each other. The organic layer may include a cured polymer such as, for example, polyacrylate.

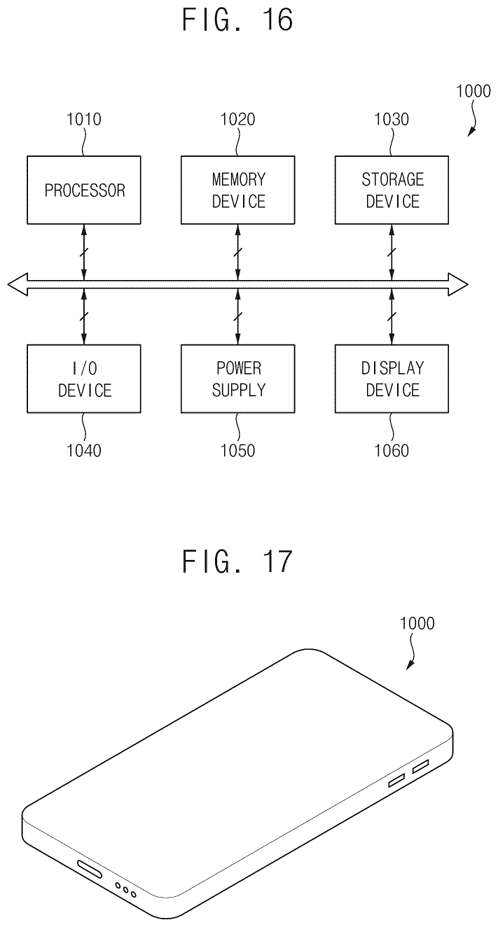

FIG. 16 is a block diagram illustrating an electronic device according to

embodiments. FIG. 17 is a diagram illustrating an example in which the electronic device of FIG. 16 is implemented as a smartphone.

Referring to FIGS. 16 and 17, an electronic device 1000 may include a processor 1010, a memory device 1020, a storage device 1030, an input/output device 1040, a power supply 1050, and a display device 1060. In this case, for example, the display device 1060 may be the display device DD of FIG. 1. In some aspects, the electronic device 1000 may further include several ports capable of communicating with a video card, a sound card, a memory card, a USB device, and/or the like.

According to an embodiment, as illustrated in the FIG. 17, the electronic device 1000 may be implemented as a smartphone. However, this is an example, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as, for example, a peripheral component interconnect (“PCI”) bus.

The memory device 1020 may store data supportive of operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Examples of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input means such as, for example, a keyboard, a keypad, a touch pad, a touch screen, and a mouse, and/or the like, and an output means such as, for example, a speaker and a printer. In an embodiment, the display device 1060 may be included in the input/output device 1040.

The power supply 1050 may supply power supportive of operation of the electronic device 1000. For example, the power supply 1050 may supply power supportive of operation of the display device 1060.

The display device 1060 may be connected to other components through buses or other communication links.

The present disclosure can be applied to various display devices. For example, the present disclosure is applicable to various display devices such as, for example, display devices for vehicles, ships and aircraft, portable communication devices, display devices for exhibition or information transmission, medical display devices, and the like.

The foregoing is illustrative of embodiments and is not to be construed as limiting thereof. Although example embodiments have been described, those skilled in the art will readily appreciate that many modifications are possible in the embodiments without materially departing from the novel teachings and advantages of the embodiments of the present disclosure. Accordingly, all such modifications are intended to be included within the scope of the embodiments of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first electrode disposed on a substrate;
a first light emitting layer disposed on the first electrode;
a first metal pattern disposed on the first light emitting layer and overlapping an edge of the first light emitting layer in a plan view;
a second metal pattern disposed on the first metal pattern and at least partially overlapping the first metal pattern in the plan view;
a side insulating layer covering a side surface of the first light emitting layer, a side surface of the first metal pattern, a side surface of the second metal pattern, and an upper surface of the second metal pattern; and
a second electrode disposed on the first light emitting layer.

2. The display device of claim 1, wherein the second metal pattern protrudes further than the first metal pattern and forms an undercut area.

3. The display device of claim 2, wherein:
the first electrode is disposed in a first pixel area, and
the second metal pattern protrudes further toward a center of the first pixel area than the first metal pattern.

4. The display device of claim 1, wherein:
the second metal pattern comprises another side surface opposite to the side surface of the second metal pattern in a cross-sectional view, and
an inner side surface of the side insulating layer and the other side surface of the second metal pattern are disposed on a same plane.

5. The display device of claim 4, wherein the second electrode covers the other side surface of the second metal pattern and the inner side surface of the side insulating layer.

6. The display device of claim 1, wherein:
the first metal pattern comprises another side surface opposite to the side surface of the first metal pattern in a cross-sectional view,
the second metal pattern comprises another side surface opposite to the side surface of the second metal pattern in the cross-sectional view, and
the second electrode covers the other side surface of the first metal pattern and the other side surface of the second metal pattern.

7. The display device of claim 6, wherein the second electrode further covers an inner side surface of the side insulating layer.

8. The display device of claim 1, further comprising:
a third electrode disposed on the substrate and spaced apart from the first electrode in the plan view; and
a second light emitting layer disposed on the third electrode and spaced apart from the first light emitting layer in the plan view.

9. The display device of claim 8, wherein the side insulating layer extends from the first light emitting layer to the second light emitting layer.

10. A display device comprising:
a first electrode disposed on a substrate;
a light emitting layer disposed on the first electrode;
a metal pattern disposed on the light emitting layer and comprising:
a first portion overlapping an edge of the light emitting layer in a plan view; and
a second portion disposed on the first portion, at least partially overlapping the first portion in the plan view, and having a larger width than the first portion;
a side insulating layer covering a side surface of the light emitting layer, a side surface of the first portion of the metal pattern, a side surface of the second portion of the metal pattern, and an upper surface of the second portion of the metal pattern; and
a second electrode disposed on the light emitting layer.

11. The display device of claim 10, wherein:
the second portion of the metal pattern comprises another side surface opposite to the side surface of the second portion of the metal pattern in a cross-sectional view, and
an inner side surface of the side insulating layer and the other side surface of the second portion of the metal pattern are disposed on a same plane.

12. The display device of claim 11, wherein the second electrode covers the other side surface of the second portion of the metal pattern and the inner side surface of the side insulating layer.

13. The display device of claim 10, wherein the first portion of the metal pattern comprises a material different from a material comprised in the second portion of the metal pattern.

14. The display device of claim 10, wherein:
the first portion of the metal pattern comprises another side surface opposite to the side surface of the first portion of the metal pattern in a cross-sectional view,
the second portion of the metal pattern comprises another side surface opposite to the side surface of the second portion of the metal pattern in the cross-sectional view, and
the second electrode covers the other side surface of the first portion of the metal pattern and the other side surface of the second portion of the metal pattern.

15. The display device of claim 14, wherein the second electrode further covers an inner side surface of the side insulating layer.

16. A method of manufacturing a display device, the method comprising:
forming a first electrode on a substrate;
forming a preliminary light emitting layer covering the first electrode;
forming a first metal layer covering the preliminary light emitting layer;
forming a second metal layer covering the first metal layer;
forming a light emitting layer by removing a portion of the preliminary light emitting layer;
forming a first preliminary metal pattern by removing a portion of the first metal layer;
forming a second preliminary metal pattern by removing a portion of the second metal layer;
forming a preliminary side insulating layer covering the light emitting layer, the first preliminary metal pattern, and the second preliminary metal pattern;
forming a side insulating layer by removing a portion of the preliminary side insulating layer;
forming a first metal pattern by removing a portion of the first preliminary metal pattern;
forming a second metal pattern by removing a portion of the second preliminary metal pattern; and
forming a second electrode on the light emitting layer.

17. The method of claim 16, wherein the portion of the preliminary side insulating layer and the portion of the second preliminary metal pattern are simultaneously removed by a dry etching process.

18. The method of claim 16, wherein:
the portion of the first preliminary metal pattern is removed through a wet etching process, and
the first metal pattern is formed such that a width of the first metal pattern is smaller than a width of the second metal pattern.

19. The method of claim 16, wherein the portion of the preliminary light emitting layer, the portion of the first metal layer, and the portion of the second metal layer are simultaneously removed.

20. The method of claim 16, wherein the forming of the side insulating layer and the forming of the second metal pattern comprises:
forming a photoresist layer in a non-light emitting area on the preliminary side insulating layer; and
removing a portion of the preliminary side insulating layer and a portion of the second preliminary metal pattern through a dry etching process.
